(19) United States
(12) Patent Application Publication
(10) Pub. No.: US 2006/0019204 A1
(43) Pub. Date: Jan. 26, 2006

(54) Exposure system, exposure method and method for fabricating semiconductor device

(75) Inventors: Masayuki Endo, Osaka (JP); Masaru Sasago, Osaka (JP)

Correspondence Address: MCDERMOTT WILL & EMERY LLP, 600 13TH STREET, N.W., WASHINGTON, DC, 20005-3096, US

(73) Assignee: MATSUSHITA ELECTRIC INDUSTRIAL CO., LTD.

(21) Appl. No.: 11/151,541

(22) Filed: Jun. 14, 2005

(30) Foreign Application Priority Data
Jul. 21, 2004 (JP) 2004-212839

(51) Int. Cl. G03B 27/00; G03F 7/20

(52) U.S. Cl. 430/395; 355/18

(57) ABSTRACT

An exposure system includes an exposure part for irradiating a resist film formed on a substrate with exposing light through a mask with a liquid provided on the resist film; and a liquid supply part for supplying the liquid to the exposure part. The liquid supplying part includes a plurality of liquid units respectively containing a plurality of liquids having different refractive indexes, and a selection unit for selecting one liquid unit from the plural liquid units and supplying a liquid contained in the selected liquid unit to the exposure part.

### CROSS-REFERENCE TO RELATED APPLICATIONS

This application claims priority under 35 U.S.C. §119 on Patent Application No. 2004-212839 filed in Japan on Jul. 21, 2004, the entire contents of which are hereby incorporated by reference.

### BACKGROUND OF THE INVENTION

The present invention relates to an exposure system, an exposure method and a method for fabricating a semiconductor device for immersion exposure for use in fabrication process or the like for semiconductor devices.

In accordance with the increased degree of integration of semiconductor integrated circuits and downsizing of semiconductor devices, there are increasing demands for further rapid development of lithography technique. Currently, pattern formation is carried out through photolithography using exposing light of a mercury lamp, KrF excimer laser, ArF excimer laser or the like, and use of F₂ laser lasing at a shorter wavelength is being examined. However, since there remain a large number of problems in exposure systems and resist materials, photolithography using exposing light of a shorter wavelength has not been put to practical use.

In these circumstances, immersion lithography has been recently proposed for realizing further refinement of patterns by using conventional exposing light (for example, see M. Switkes and M. Rothschild, “Immersion lithography at 157 nm”, J. Vac. Sci. Technol., Vol. B19, p. 2353 (2001)).

In the immersion lithography, a region in an exposure system sandwiched between a projection lens and a resist film formed on a wafer is filled with a liquid having a refractive index n (whereas n>1) and therefore, the NA (numerical aperture) of the exposure system has a value n·NA. As a result, the resolution of the resist film can be improved.

Now, a conventional pattern formation method employing the immersion lithography will be described with reference to FIGS. 10A through 10D and 11A through 11D.

First, a positive chemically amplified resist material having the following composition is prepared:

| | |
|---|---|
| Base polymer: poly((norbornene-5-methylene-t-butylcarboxylate) (50 mol %) - | 2 g |
| (maleic anhydride) (50 mol %)) | |
| Acid generator: triphenylsulfonium triflate | 0.06 g |
| Quencher: triethanolamine | 0.002 g |
| Solvent: propylene glycol monomethyl ether acetate | 20 g |

Next, as shown in FIG. 10A, the aforementioned chemically amplified resist material is applied on a substrate 1A so as to form a resist film 2 with a thickness of 0.35 μm.

Then, as shown in FIG. 10B, with water 3 for immersion exposure having a refractive index of 1.44 provided between the resist film 2 and a projection lens (not shown), pattern exposure is carried out by irradiating the resist film 2 with exposing light 4 of ArF excimer laser with NA of 0.68 through a first mask 5A.

After the pattern exposure, as shown in FIG. 10C, the resist film 2 is baked with a hot plate at a temperature of 105° C. for 60 seconds, and the resultant resist film is developed with a tetramethylammonium hydroxide developer in a concentration of 0.26 N. In this manner, a first resist pattern 2a made of an unexposed portion of the resist film 2 and having a line width of 0.10 μm is formed as shown in FIG. 10D.

Next, as shown in FIG. 11A, the aforementioned chemically amplified resist material is applied on a substrate 1B so as to form a resist film 2 with a thickness of 0.35 μm.

Then, as shown in FIG. 11B, with water 3 for immersion exposure having a refractive index of 1.44 provided between the resist film 2 and the projection lens (not shown), pattern exposure is carried out by irradiating the resist film 2 with the exposing light 4 of ArF excimer laser with NA of 0.68 through a second mask 5B.

After the pattern exposure, as shown in FIG. 11C, the resist film 2 is baked with a hot plate at a temperature of 105° C. for 60 seconds, and the resultant resist film is developed with a tetramethylammonium hydroxide developer in a concentration of 0.26 N. In this manner, a second resist pattern 2b made of an unexposed portion of the resist film 2 is formed as shown in FIG. 11D.

### SUMMARY OF THE INVENTION

In the conventional pattern formation method employing the immersion lithography, however, although the first resist pattern with a line width of 0.10 μm is in a good shape, the second resist pattern 2b with a line width of 0.07 μm is in a defective shape as shown in FIG. 11D.

The present inventors have variously examined the reason why the resist pattern formed by the conventional immersion lithography is in a defective shape, resulting in finding that the second resist pattern 2b corresponds to the critical resolution.

However, the present inventors have also achieved novel finding that when the resolution of exposing light is simply increased, the focal depth is reduced and hence a resist pattern cannot be formed in a good shape due to the reduced focal depth.

In order to improve the resolution attained in the immersion lithography, for example, the value of the refractive index of the immersion liquid is increased. However, merely when the value of the refractive index is increased, the exposure is always performed with a large numerical aperture regardless of the degree of fineness of a pattern to be formed, and therefore, the focal depth is reduced due to the large numerical aperture in forming some kinds of patterns.

In general, the resolution is represented by the following Formula 1:
Resolution=K1·λ/NA Formula 1
wherein K1 is a constant determined depending upon process conditions and an exposure optical system, λ is the wavelength of exposing light and NA is a numerical aperture. Accordingly, it is understood from Formula 1 that the value of the resolution itself is reduced, namely, the resolution is improved, by reducing the wavelength of the exposing light or increasing the numerical aperture.

On the other hand, since the focal depth is reduced in inverse proportion to a square of the numerical aperture NA of a lens, as the resolution is improved, the focal depth is abruptly reduced, and hence, it is difficult to focalize.

In the immersion lithography, a space between an exposure lens and a resist film is filled with a material having a different refractive index from the air, such as a liquid like water in general, so as to increase the value of the refractive index. As a result, the value of the numerical aperture of the exposure system can be increased, so that high resolution can be attained without reducing the wavelength of the exposing light.

As described above, however, when the resolution is improved by increasing the value of the refractive index of the liquid provided between the exposure lens and the resist film, the focal depth is disadvantageously reduced.

In consideration of the aforementioned conventional problem, an object of the invention is forming a pattern in a good shape by attaining both the improvement of the resolution and the retention of the focal depth in the immersion lithography.

In order to achieve the object, according to the invention, a plurality of immersion exposure liquids having different values of refractive indexes are properly used in accordance with the pattern size in a layout in the immersion exposure.

First, a layout requiring high resolution will be described.

Examples of the layout requiring high resolution are a gate pattern of a field effect transistor, an interconnect pattern on a first layer and a circuit pattern of a circuit with a high integration density. Also, the shape of such a layout is, for example, a hole pattern with a high aspect ratio. In particular, for a layout with a distance between adjacent interconnects of 0.25 μm or less or a layout used for forming a pattern of a contact hole or the like to be electrically connected to a gate electrode, an immersion liquid having a refractive index of, for example, approximately 1.56 is preferably used.

On the contrary, an example of a layout not necessarily requiring high resolution is a layout pattern with a large line width such as a hole pattern used for forming a bonding pad or a global interconnect pattern formed in an upper layer.

Accordingly, highly accurate pattern formation can be carried out by examining and selecting an appropriate refractive index in accordance with the layout of a pattern to be formed and supplying an immersion liquid corresponding to the selected refractive index in the exposure.

The present invention was devised on the basis of the aforementioned findings and is specifically practiced as follows:

The exposure system of this invention includes an exposure part for irradiating a resist film formed on a substrate with exposing light through a mask with a liquid provided on the resist film; and a liquid supply part for supplying the liquid to the exposure part, and the liquid supplying part includes a plurality of liquid units respectively containing a plurality of liquids having different refractive indexes, and a selection unit for selecting one liquid unit from the plurality of liquid units and supplying a liquid contained in the selected liquid unit to the exposure part.

In the exposure system of this invention, the liquid supply part selects one of the plural liquids having different refractive indexes and supplies the selected liquid to the exposure part. Therefore, the immersion liquids having different refractive indexes can be properly used in accordance with the pattern size of a layout of a pattern to be formed. Specifically, in the exposure of what is called a fine pattern with a comparatively small pattern size, a liquid having a relatively large refractive index can be used. On the other hand, in the exposure of what is called a rough pattern with a comparatively large pattern size, a liquid having a relatively small refractive index can be used. Therefore, the resolution of a pattern with a comparatively small size can be improved. Also, the focal depth can be prevented from reducing in the exposure of a pattern with a comparatively large size. Thus, patterns can be formed in a good shape regardless of their pattern sizes.

The exposure method of this invention includes the steps of exposing a first pattern onto a first resist film formed on a first substrate with a first liquid provided on the first resist film; and exposing a second pattern having a different pattern size from the first pattern onto a second resist film formed on a second substrate with a second liquid having a different refractive index from the first liquid provided on the second resist film.

In this case, the second pattern preferably has a larger pattern size than the first pattern. Also in this case, the second liquid preferably has a smaller refractive index than the first liquid.

In the exposure method of this invention, for example, in the case where the second pattern having a larger pattern size than the first pattern is exposed onto the second resist film formed on the second substrate, the pattern exposure of the second pattern is performed with the second liquid having a different refractive index from the first liquid, and more specifically, having a smaller refractive index than the first liquid, provided on the second resist film. Therefore, even when the refractive index of the first liquid is increased so as to improve the resolution of the first pattern, the focal depth can be prevented from reducing in the exposure of the second pattern having a larger pattern size than the first pattern. As a result, patterns can be formed in a good shape regardless of the degree in the pattern density. In particular, in accordance with development in complexity and fineness of device structures, interconnects are formed in a multilayered structure with a larger number of layers, and therefore, it is necessary to form patterns different in the size on respective layers. Accordingly, the invention is useful in performing exposure in accordance with each pattern size while keeping the focal depth as much as possible.

The method for fabricating a semiconductor device of this invention includes the steps of forming a first resist film on a first substrate; performing first pattern exposure by irradiating the first resist film with exposing light through a first mask having a first pattern with a first liquid provided on the first resist film; forming a first resist pattern by developing the first resist film after the first pattern exposure; forming a second resist film on a second substrate; performing second pattern exposure by irradiating the second resist film with the exposing light through a second mask having a second pattern with a second liquid having a different refractive index from the first liquid provided on the second resist film; and forming a second resist pattern by developing the second resist film after the second pattern exposure.

In the method for fabricating a semiconductor device of this invention, the second pattern exposure is performed with the second liquid having a different refractive index from the first liquid provided on the second resist film separately from the first pattern exposure performed with the first liquid provided on the first resist film. Therefore, for example, a liquid having a relatively large refractive index can be used in the first pattern exposure of the first pattern with a comparatively small size. On the other hand, the second liquid having a smaller refractive index than the first liquid can be used in the second pattern exposure of the second pattern having a larger pattern size than the first pattern. Accordingly, the resolution of the first pattern with a small pattern size can be improved, and in addition, the focal depth of the second pattern exposure for the second pattern having a larger pattern size than the first pattern can be prevented from reducing. As a result, patterns can be formed in a good shape regardless of their pattern sizes.

In the method for fabricating a semiconductor device, when the second pattern has a larger pattern size than the first pattern, the second liquid preferably has a smaller refractive index than the first liquid.

In the exposure method or the method for fabricating a semiconductor device of this invention, the first substrate and the second substrate may be one and the same substrate.

In the exposure method or the method for fabricating a semiconductor device of this invention, the first pattern and the second pattern different in the pattern density are effectively formed respectively by using liquids having different refractive indexes. In particular, since a pattern with a high density includes a large number of narrow regions sandwiched between patterns, high resolution is required. Therefore, a liquid with a comparatively large refractive index is preferably used in this case.

In the exposure system, the exposure method or the method for fabricating a semiconductor device of this invention, the immersion liquid can be water, water including an additive or perfluoropolyether.

In this case, the additive can be cesium sulfate or ethyl alcohol.

In the exposure system, the exposure method or the method for fabricating a semiconductor device of this invention, the exposing light can be KrF excimer laser, Xe₂ laser, ArF excimer laser, F₂ laser, KrAr laser or Ar₂ laser.

### BRIEF DESCRIPTION OF THE DRAWINGS

FIG. 1A is a block (system) diagram of a semiconductor manufacturing apparatus employing immersion lithography according to the invention and FIG. 1B is a block diagram of an immersion liquid supply part of the semiconductor manufacturing apparatus;

FIG. 2 is a schematic cross-sectional view of a principal part of a pattern exposure part of the semiconductor manufacturing apparatus of the invention;

FIGS. 3A, 3B, 3C and 3D are cross-sectional views for showing procedures in a method for fabricating a semiconductor device according to Embodiment 1 of the invention;

FIGS. 4A, 4B, 4C and 4D are cross-sectional views for showing other procedures in the method for fabricating a semiconductor device according to Embodiment 1 of the invention;

FIGS. 5A, 5B, 5C and 5D are cross-sectional views for showing procedures in a method for fabricating a semiconductor device according to Embodiment 2 of the invention;

FIGS. 6A, 6B, 6C and 6D are cross-sectional views for showing other procedures in the method for fabricating a semiconductor device according to Embodiment 2 of the invention;

FIGS. 7A, 7B, 7C and 7D are cross-sectional views for showing other procedures in the method for fabricating a semiconductor device according to Embodiment 2 of the invention;

FIGS. 8A, 8B, 8C and 8D are cross-sectional views for showing procedures in a method for fabricating a semiconductor device according to Embodiment 3 of the invention;

FIGS. 9A, 9B, 9C and 9D are cross-sectional views for showing other procedures in the method for fabricating a semiconductor device according to Embodiment 3 of the invention;

FIGS. 10A, 10B, 10C and 10D are cross-sectional views for showing procedures in a conventional method for fabricating a semiconductor device employing the immersion exposure; and

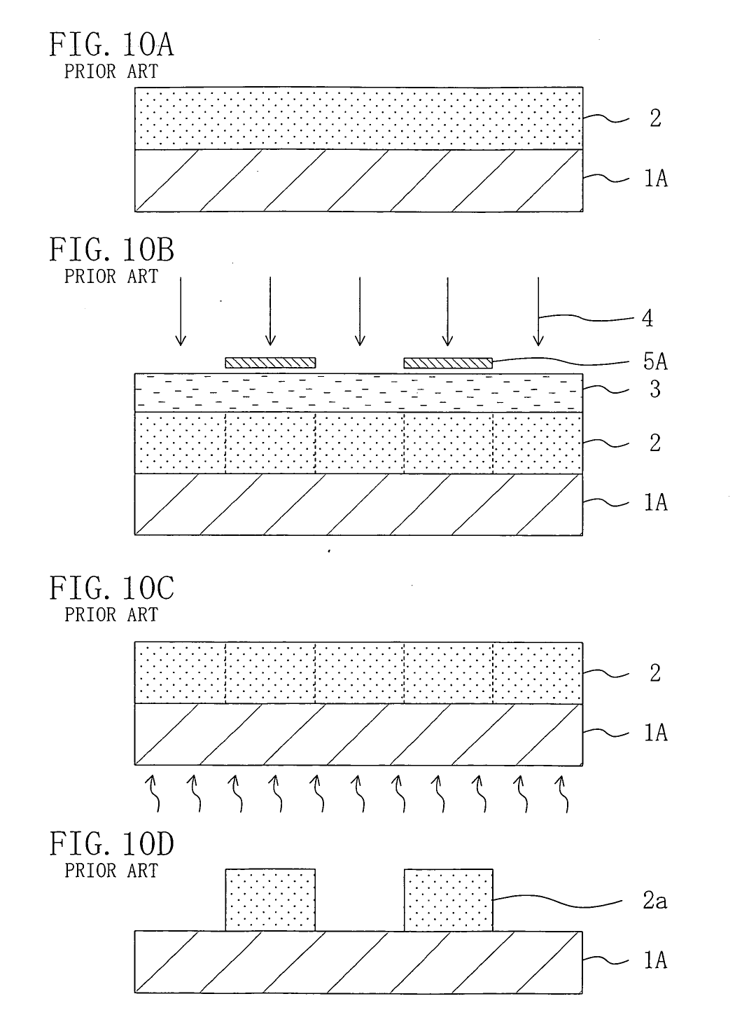

FIGS. 11A, 11B, 11C and 11D are cross-sectional views for showing other procedures in the conventional method for fabricating a semiconductor device employing the immersion lithography.

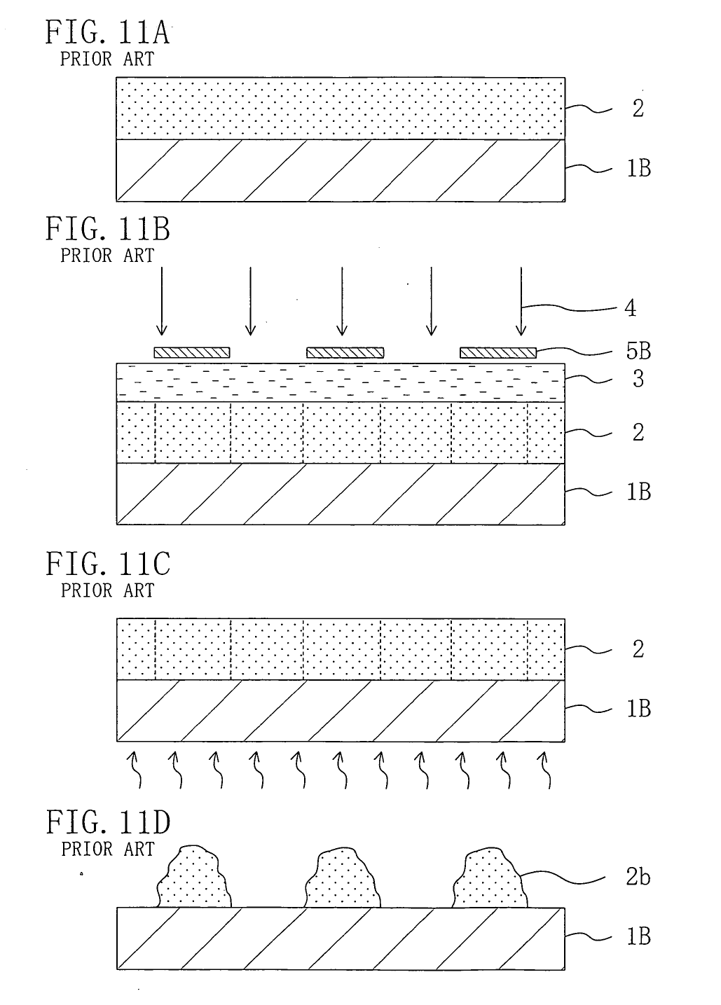

### DETAILED DESCRIPTION OF THE INVENTION

### Embodiment 1

Embodiment 1 of the invention will now be described with reference to the accompanying drawings.

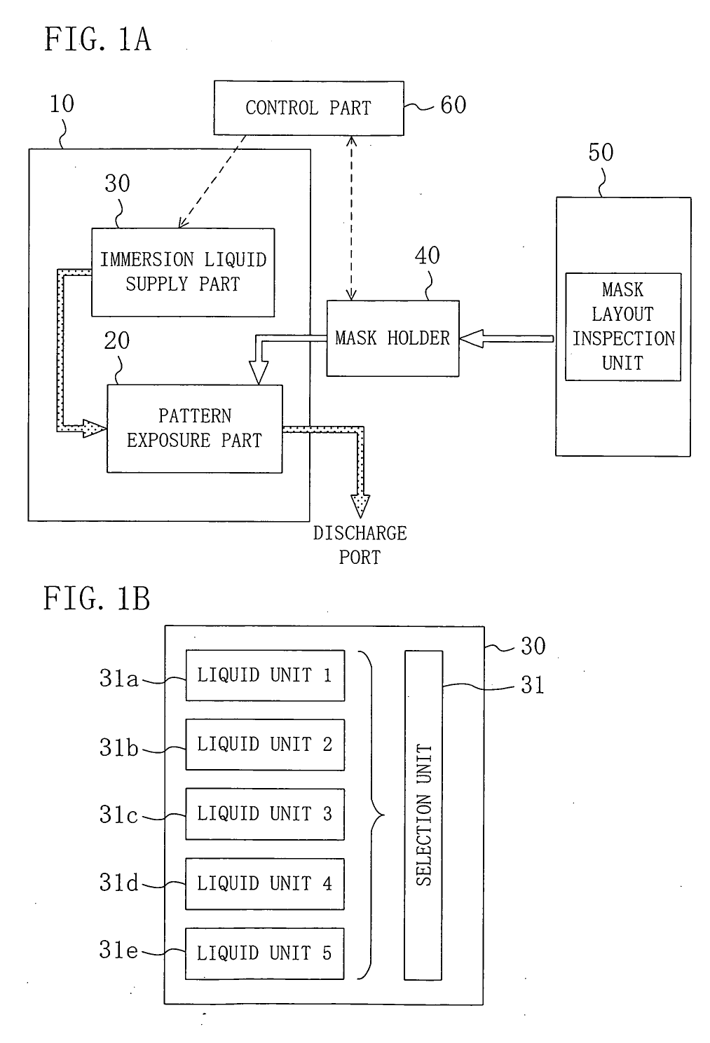

FIG. 1A schematically shows the system architecture of a semiconductor manufacturing apparatus employing immersion lithography according to Embodiment 1 of the invention, and FIG. 1B is a block diagram of an immersion liquid supply part of the semiconductor manufacturing apparatus.

As shown in FIG. 1A, the semiconductor manufacturing apparatus 10 of the invention includes a pattern exposure part 20 for performing pattern exposure on a resist film formed on a wafer; an immersion liquid supply part 30 for supplying an immersion liquid to the pattern exposure part 20; and a control part 60 for determining a pattern of a mask (reticle) to be used.

A mask holder 40 for temporarily storing a plurality of masks respectively having design patterns transports a mask to be used in exposure to the pattern exposure part 20. Each mask is subjected to a predetermined inspection by a mask layout inspection unit 50 and is then stored in the mask holder 40.

The control part 60 acquires information of a pattern size of the design pattern of each mask stored in the mask holder 40 and transported to the pattern exposure part 20. The control part 60 selects, on the basis of the thus acquired information, an immersion liquid having an appropriate refractive index in accordance with the pattern size and outputs the resultant selection instruction to the immersion liquid supply part 30.

FIG. 1B shows an example of the architecture of the immersion liquid supply part 30. As shown in FIG. 1B, the immersion liquid supply part 30 includes a selection unit 31 for containing a plurality of, for example, five kinds of liquid units 31a through 31e different in the refractive index.

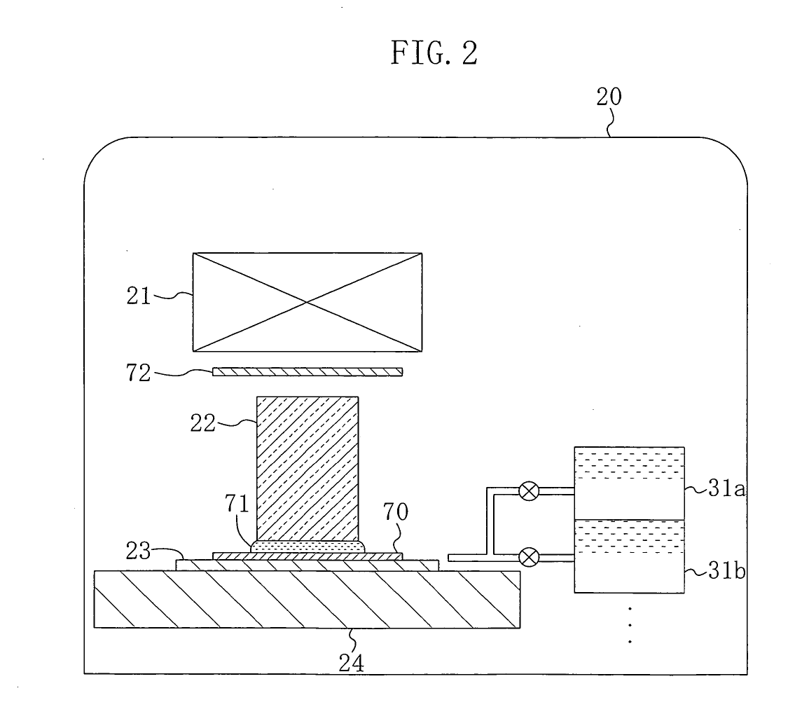

FIG. 2 is a schematic cross-sectional view of the semiconductor manufacturing apparatus 10 of the invention. As shown in FIG. 2, the semiconductor manufacturing apparatus 10 of this invention is provided within a chamber 20. The semiconductor manufacturing apparatus 10 includes an illumination optical system 21 corresponding to a light source for exposing a design pattern on a resist film (not shown) applied on a wafer 70 placed on a wafer stage 23, and a surface plate 24 for movably holding the wafer stage 23 holding the wafer 70. A mask (reticle) 72 having a design pattern to be transferred onto the resist film is disposed below the illumination optical system 21. Exposing light emitted from the illumination optical system 21 and entering through the mask 72 is projected through an immersion liquid 71 onto the resist film on the wafer 70. During the exposure, a projection lens 22 and the immersion liquid 71 are disposed to be in contact with each other.

During the exposure, the immersion liquid 71 used for increasing the numerical aperture value of the illumination optical system 21 is supplied onto the resist film on the wafer 70 selectively from a plurality of liquid units 31a, 31b, etc contained in the immersion liquid supply part 30. At this point, the supplied liquid 71 is provided to be in connect with the surface of the projection lens 22.

In this manner, in the semiconductor manufacturing apparatus (exposure system) of this invention, one of plural liquids having different refractive indexes is selected to be supplied by the immersion liquid supply part 30, and hence, the immersion liquids having different refractive indexes can be properly used in accordance with the pattern size of the mask 72. Therefore, a liquid having a relatively large refractive index can be used in the pattern exposure of a pattern with a comparatively small pattern size, and a liquid having a relatively small refractive index can be used in the pattern exposure of a pattern with a comparatively large pattern size. Accordingly, the resolution of a pattern with a comparatively small size can be improved while the focal depth can be prevented from reducing in the pattern exposure of a pattern with a comparatively large size, so that any pattern can be formed in a good shape regardless of the pattern size.

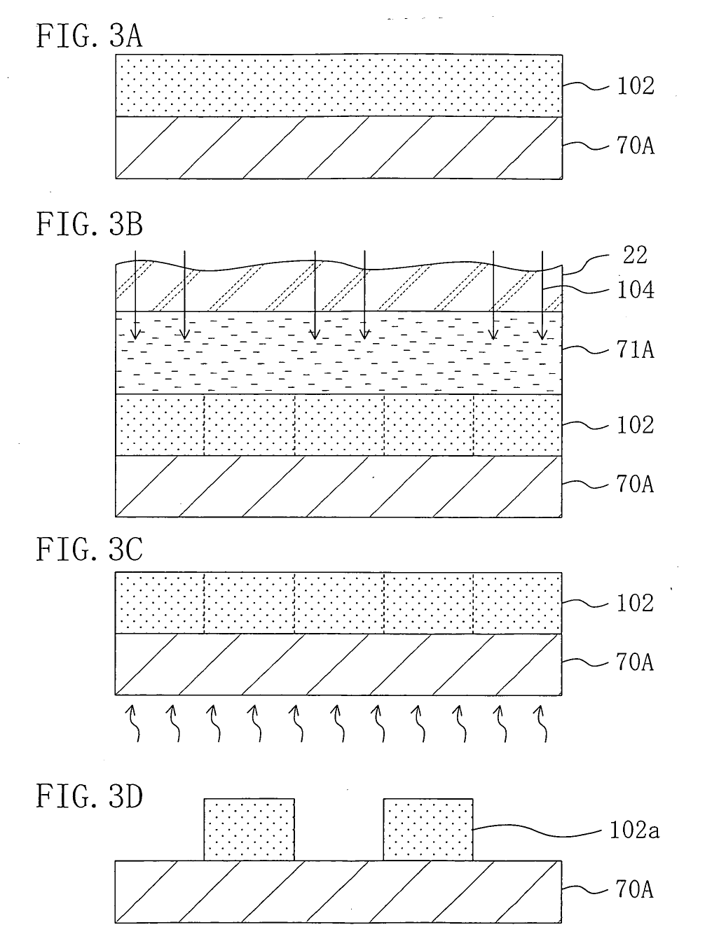

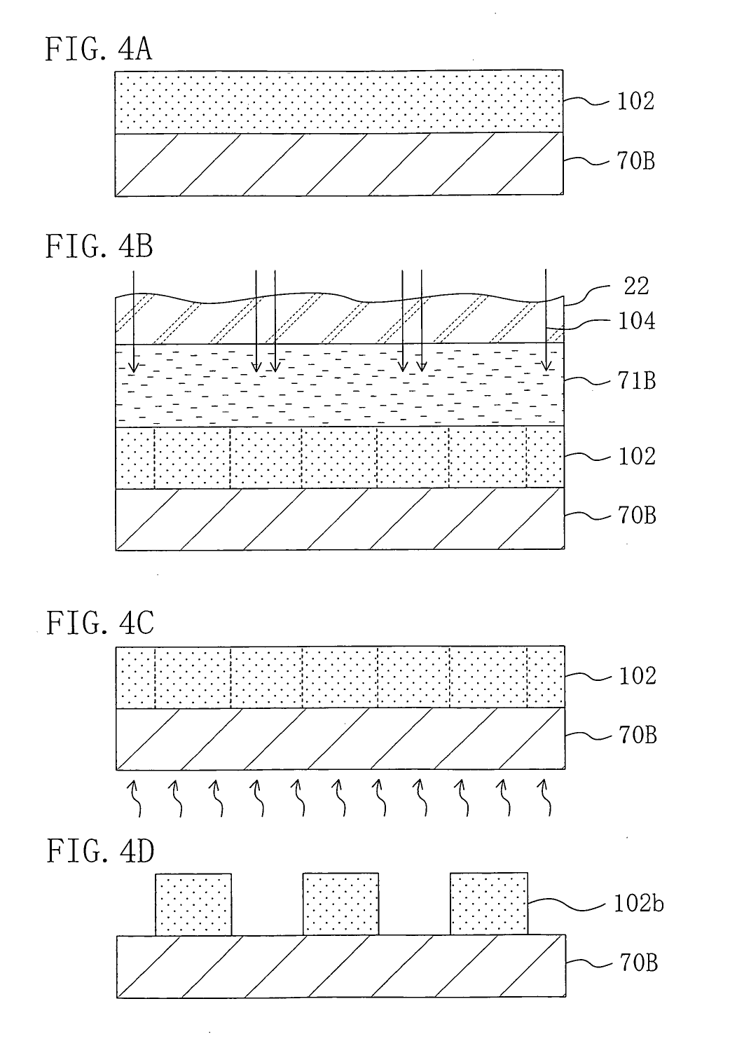

Now, a method for fabricating a semiconductor device (pattern formation method) according to Embodiment 1 using the semiconductor manufacturing apparatus of the invention will be described with reference to FIGS. 3A through 3D and 4A through 4D.

First, a positive chemically amplified resist material having the following composition is prepared:

| | |
|---|---|
| Base polymer: poly((norbornene-5-methylene-t-butylcarboxylate) (50 mol %) - | 2 g |
| (maleic anhydride) (50 mol %)) | |
| Acid generator: triphenylsulfonium triflate | 0.06 g |
| Quencher: triethanolamine | 0.002 g |
| Solvent: propylene glycol monomethyl ether acetate | 20 g |

Next, as shown in FIG. 3A, the aforementioned chemically amplified resist material is applied on a substrate 70A so as to form a resist film 102 with a thickness of 0.35 μm.

Then, as shown in FIG. 3B, a first immersion liquid 71A of water having a refractive index of 1.44 is provided between the resist film 102 and a projection lens 22. Under this condition, pattern exposure is carried out by irradiating the resist film 102 through a first mask (not shown) with exposing light 104 of ArF excimer laser with NA of 0.68. It is previously determined by the control part 60 that the pattern size of the first mask is comparatively large, and therefore, the water is selected as the immersion liquid to be supplied as the first liquid 71A. At this point, the contents of the determination of the mask pattern made by the control part 60 before the pattern exposure will be described. In the control part 60, a mask to be used in the exposure is verified in deviation of arrangement of a layout pattern, the size of a line width and the like before the pattern exposure. Also, a difference from a mask pattern used in previous exposure is obtained, so as to verify an appropriate refractive index of the immersion liquid to be used. When the mask determination made by the control part 60 is carried out before every exposure, a more appropriate refractive index can be definitely verified. Alternatively, when the determination is performed not before every exposure but at timing of exchanging a mask, the determination (verification) performed before the exposure can be omitted if the same mask is used, so as to improve the throughput.

After the pattern exposure, as shown in FIG. 3C, the resist film 102 is baked with a hot plate at a temperature of 105° C. for 60 seconds, and thereafter, the resultant resist film 102 is developed with a tetramethylammonium hydroxide developer in a concentration of 0.26 N. In this manner, a first resist pattern 102a made of an unexposed portion of the resist film 102 and having a line width of 0.10 μm is formed in a good shape as shown in FIG. 3D.

Next, as shown in FIG. 4A, the aforementioned chemically amplified resist material is applied on a substrate 70B so as to form a resist film 102 with a thickness of 0.35 μm.

Then, as shown in FIG. 4B, a second immersion liquid 71B of water including cesium sulfate (CsSO₄) in a concentration of 5 wt % for attaining a refractive index of 1.56 is provided between the resist film 102 and the projection lens 22. Under this condition, pattern exposure is carried out by irradiating the resist film 102 through a second mask (not shown) with the exposing light 104 of ArF excimer laser with NA of 0.68. It is previously determined by the control part 60 that the pattern size of the second mask is comparatively small, and therefore, the water including cesium sulfate is selected to be supplied as the second liquid 71B.

After the pattern exposure, as shown in FIG. 4C, the resist film 102 is baked with a hot plate at a temperature of 105° C. for 60 seconds, and thereafter, the resultant resist film 102 is developed with a tetramethylammonium hydroxide developer in a concentration of 0.26 N. In this manner, a second resist pattern 102b made of an unexposed portion of the resist film 102 and having a line width of 0.07 μm is formed in a good shape as shown in FIG. 4D.

In this manner, according to Embodiment 1, in the case where the first pattern exposure using the first mask and the second pattern exposure using the second mask having a smaller pattern size than the first mask are carried out, the first liquid 71A having a refractive index of 1.44 and the second liquid 71B having a refractive index of 1.56 are respectively used in the first pattern exposure and the second pattern exposure. Therefore, since the focal depth can be prevented from reducing in the first pattern exposure, the first resist pattern 102a with a large pattern size can be easily focused and can be formed in a good shape. In addition, since the second liquid 71B having a larger refractive index than the first liquid 71A is used in the second pattern exposure, the second resist pattern 102b can be formed also in a good shape. Accordingly, the resist patterns can be formed in a good shape regardless of their pattern sizes.

### Embodiment 2

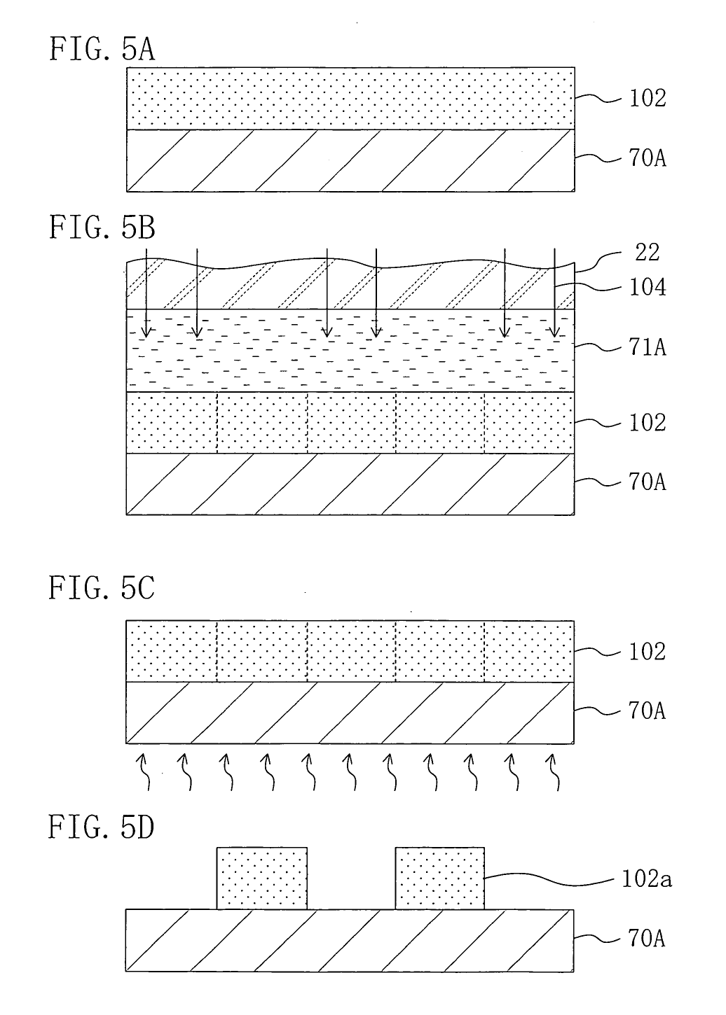

Now, a method for fabricating a semiconductor device (pattern formation method) according to Embodiment 2 using the semiconductor manufacturing apparatus of the invention will be described with reference to FIGS. 5A through 5D, 6A through 6D and 7A through 7D.

First, a positive chemically amplified resist material having the following composition is prepared:

| | |
|---|---|
| Base polymer: poly((norbornene-5-methylene-t-butylcarboxylate) (50 mol %) - | 2 g |
| (maleic anhydride) (50 mol %)) | |
| Acid generator: triphenylsulfonium triflate | 0.06 g |
| Quencher: triethanolamine | 0.002 g |
| Solvent: propylene glycol monomethyl ether acetate | 20 g |

Next, as shown in FIG. 5A, the aforementioned chemically amplified resist material is applied on a substrate 70A so as to form a resist film 102 with a thickness of 0.35 μm.

Then, as shown in FIG. 5B, a first immersion liquid 71A of water having a refractive index of 1.44 is provided between the resist film 102 and a projection lens 22. Under this condition, pattern exposure is carried out by irradiating the resist film 102 through a first mask (not shown) with exposing light 104 of ArF excimer laser with NA of 0.68. It is previously determined by the control part 60 that the pattern size of the first mask is comparatively large, and therefore, the water is selected to be supplied as the first liquid 71A.

After the pattern exposure, as shown in FIG. 5C, the resist film 102 is baked with a hot plate at a temperature of 105° C. for 60 seconds, and thereafter, the resultant resist film 102 is developed with a tetramethylammonium hydroxide developer in a concentration of 0.26 N. In this manner, a first resist pattern 102a made of an unexposed portion of the resist film 102 and having a line width of 0.10 μm is formed in a good shape as shown in FIG. 5D.

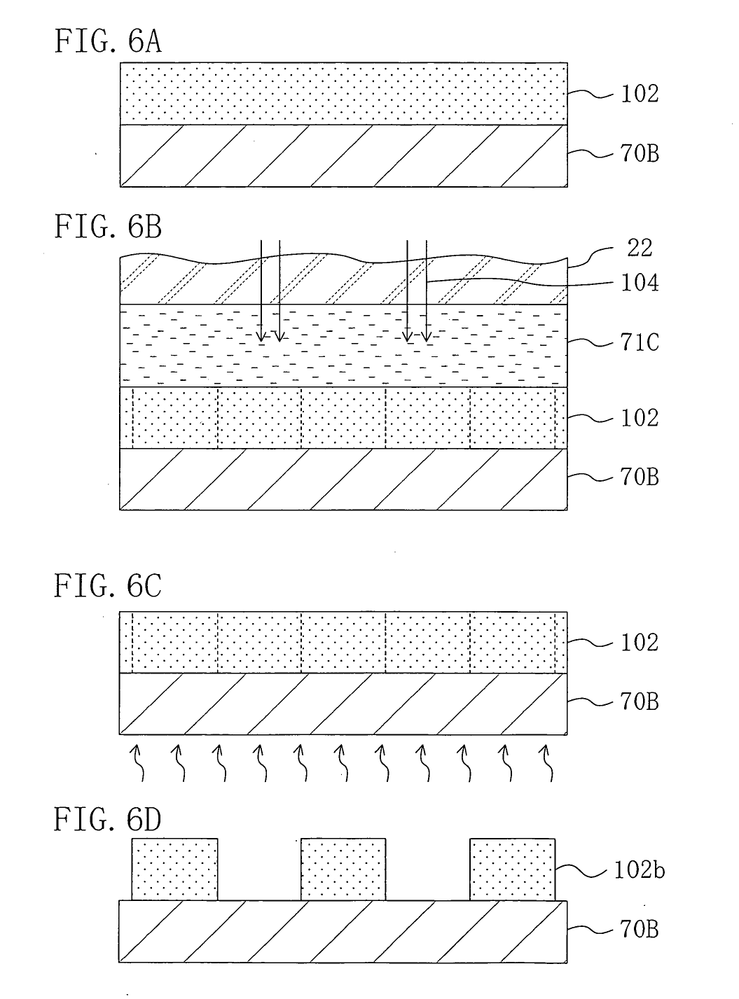

Next, as shown in FIG. 6A, the aforementioned chemically amplified resist material is applied on a substrate 70B so as to form a resist film 102 with a thickness of 0.35 μm.

Then, as shown in FIG. 6B, a second immersion liquid 71C of water including ethyl alcohol (C₂H₅OH) in a concentration of 5 wt % for attaining a refractive index of 1.49 is provided between the resist film 102 and the projection lens 22. Under this condition, pattern exposure is carried out by irradiating the resist film 102 through a second mask (not shown) with the exposing light 104 of ArF excimer laser with NA of 0.68. It is previously determined by the control part 60 that the pattern size of the second mask is smaller than the pattern size of the first mask, and therefore, the water including ethyl alcohol is selected to be supplied as the second liquid 71C.

After the pattern exposure, as shown in FIG. 6C, the resist film 102 is baked with a hot plate at a temperature of 105° C. for 60 seconds, and thereafter, the resultant resist film 102 is developed with a tetramethylammonium hydroxide developer in a concentration of 0.26 N. In this manner, a second resist pattern 102b made of an unexposed portion of the resist film 102 and having a line width of 0.08 μm is formed in a good shape as shown in FIG. 6D.

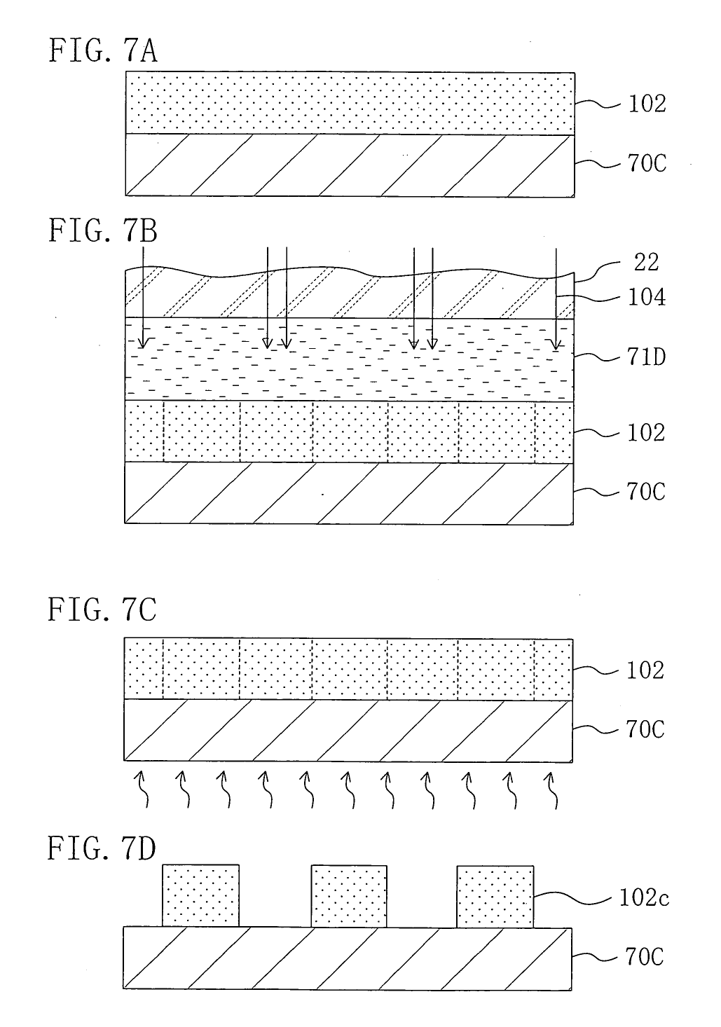

Next, as shown in FIG. 7A, the aforementioned chemically amplified resist material is applied on a substrate 70C so as to form a resist film 102 with a thickness of 0.35 μm.

Then, as shown in FIG. 7B, a third immersion liquid 71D of water including cesium sulfate (CsSO₄) in a concentration of 5 wt % for attaining a refractive index of 1.56 is provided between the resist film 102 and a projection lens 22. Under this condition, pattern exposure is carried out by irradiating the resist film 102 through a third mask (not shown) with exposing light 104 of ArF excimer laser with NA of 0.68. It is previously determined by the control part 60 that the pattern size of the third mask is smaller than the pattern size of the second mask, and therefore, the water including cesium sulfate is selected to be supplied as the third liquid 71D.

After the pattern exposure, as shown in FIG. 7C, the resist film 102 is baked with a hot plate at a temperature of 105° C. for 60 seconds, and thereafter, the resultant resist film 102 is developed with a tetramethylammonium hydroxide developer in a concentration of 0.26 N. In this manner, a third resist pattern 102c made of an unexposed portion of the resist film 102 and having a line width of 0.07 μm is formed in a good shape as shown in FIG. 7D.

In this manner, according to Embodiment 2, in the case where the first pattern exposure using the first mask, the second pattern exposure using the second mask having a smaller pattern size than the first mask and the third pattern exposure using the third mask having a smaller pattern size than the second mask are carried out, the first liquid 71A having a refractive index of 1.44, the second liquid 71C having a refractive index of 1.49 and the third liquid 71D having a refractive index of 1.56 are respectively used in the first, second and third pattern exposures. Therefore, since the focal depth can be prevented from reducing in the first pattern exposure, the first resist pattern 102a with a large pattern size can be easily focused and can be formed in a good shape. In addition, since the second liquid 71C having a larger refractive index than the first liquid 71A and the third liquid 71D having a larger refractive index than the second liquid 71C are respectively used in the second and third pattern exposures, the second resist pattern 102b and the third resist pattern 102c can be formed also in a good shape. Accordingly, the resist patterns can be formed in a good shape regardless of their pattern sizes.

### Embodiment 3

A method for fabricating a semiconductor device according to Embodiment 3 using the semiconductor manufacturing apparatus of the invention will now be described.

For providing different refractive indexes to immersion liquids, the compositions of additives in the respective immersion liquids are different in Embodiment 2. In contrast, the same additive is used but its content is changed so as to change the refractive index of an immersion liquid in Embodiment 3. Therefore, immersion liquids having various refractive indexes can be supplied without preparing a plurality of immersion liquids having different compositions.

In particular, when the content of the additive of a liquid is controlled, immersion liquids having a small difference in the refractive index can be supplied. Therefore, this embodiment is useful when the refractive index is desired to be adjusted in a minute range.

Accordingly, in the case where pattern widths and layouts are largely different, an appropriate immersion liquid is selected from a plurality of liquids respectively having different refractive indexes as in Embodiment 2, and in the case where a difference in the pattern width and the layout is small and it is necessary to adjust the refractive index in a minute range, the refractive index can be minutely changed by adjusting the content of the additive. As a result, pattern formation can be carried out in an optimum state with respect to each layout.

In this embodiment, immersion liquids used for respective exposures are contained in the liquid units 31a, etc. of the immersion liquid supply part 30 of FIG. 1B, and an immersion liquid appropriately selected in the selection unit 31 is supplied in accordance with a pattern to be exposed. The semiconductor manufacturing apparatus preferably includes means for periodically stirring each immersion liquid, and particularly, a liquid including an additive, while it is contained in each of the liquid units 31a, 31b, etc.

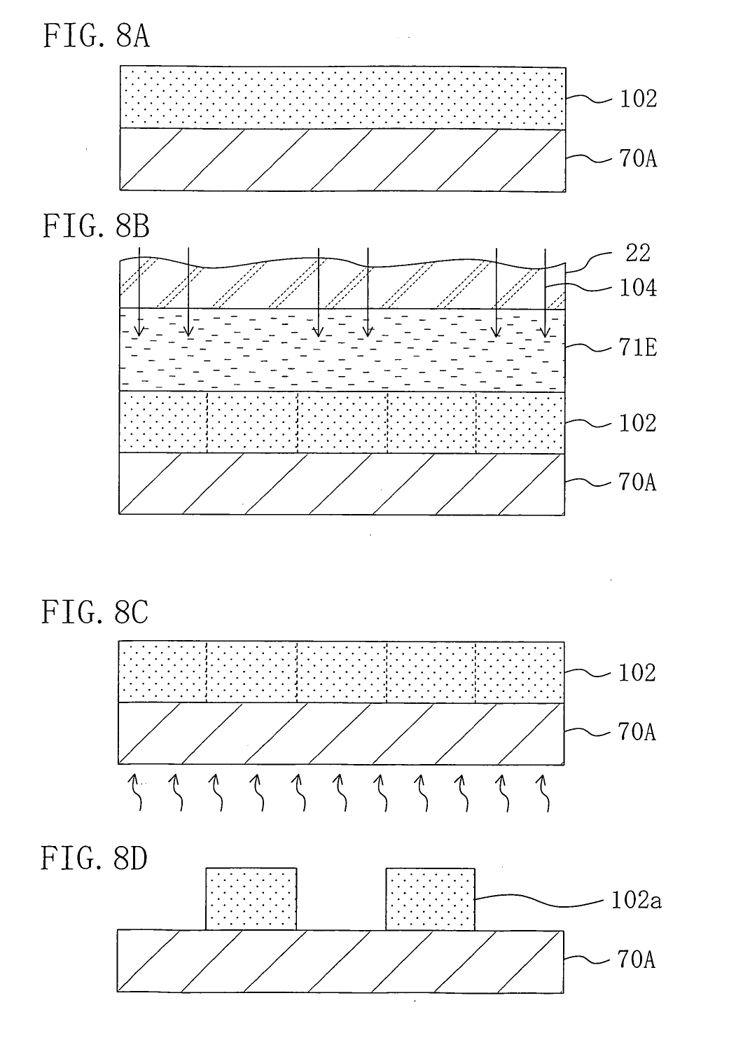

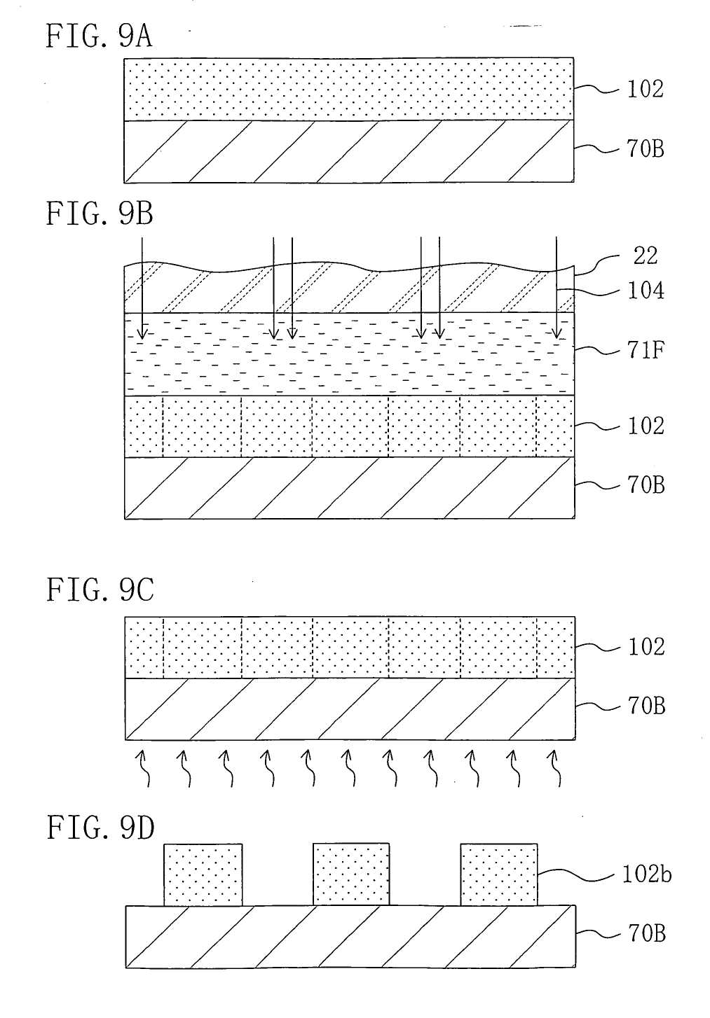

Now, a method for fabricating a semiconductor device (pattern formation method) according to Embodiment 3 using the semiconductor manufacturing apparatus of the invention will be described with reference to FIGS. 8A through 8D and 9A through 9D.

First, a positive chemically amplified resist material having the following composition is prepared:

| | |
|---|---|
| Base polymer: poly((norbornene-5-methylene-t-butylcarboxylate) (50 mol %) - | 2 g |
| (maleic anhydride) (50 mol%)) | |
| Acid generator: triphenylsulfonium triflate | 0.06 g |
| Quencher: triethanolamine | 0.002 g |
| Solvent: propylene glycol monomethyl ether acetate | 20 g |

Next, as shown in FIG. 8A, the aforementioned chemically amplified resist material is applied on a substrate 70A so as to form a resist film 102 with a thickness of 0.35 μm.

Then, as shown in FIG. 8B, a first immersion liquid 71E of water including cesium sulfate (CsSO₄) in a concentration of 3 wt % for attaining a refractive index of 1.51 is provided between the resist film 102 and a projection lens 22. Under this condition, pattern exposure is carried out by irradiating the resist film 102 through a first mask (not shown) with exposing light 104 of ArF excimer laser with NA of 0.68. It is previously determined by the control part 60 that the pattern size of the first mask is comparatively large, and therefore, the water whose refractive index is set to 1.51 by adding the cesium sulfate thereto is selected to be supplied as the first liquid 71E.

After the pattern exposure, as shown in FIG. 8C, the resist film 102 is baked with a hot plate at a temperature of 105° C. for 60 seconds, and thereafter, the resultant resist film 102 is developed with a tetramethylammonium hydroxide developer in a concentration of 0.26 N. In this manner, a first resist pattern 102a made of an unexposed portion of the resist film 102 and having a line width of 0.10 μm is formed in a good shape as shown in FIG. 8D.

Next, as shown in FIG. 9A, the aforementioned chemically amplified resist material is applied on a substrate 70B so as to form a resist film 102 with a thickness of 0.35 μm.

Then, as shown in FIG. 9B, a second immersion liquid 11F of water including cesium sulfate (CsSO₄) in a concentration of 6 wt % for attaining a refractive index of 1.58 is provided between the resist film 102 and the projection lens 22. Under this condition, pattern exposure is carried out by irradiating the resist film 102 through a second mask (not shown) with the exposing light 104 of ArF excimer laser with NA of 0.68. It is previously determined by the control part 60 that the pattern size of the second mask is smaller than the pattern size of the first mask, and therefore, the water whose refractive index is set to 1.58 by adding the cesium sulfate thereto is selected to be supplied as the second liquid 71F.

After the pattern exposure, as shown in FIG. 9C, the resist film 102 is baked with a hot plate at a temperature of 105° C. for 60 seconds, and thereafter, the resultant resist film 102 is developed with a tetramethylammonium hydroxide developer in a concentration of 0.26 N. In this manner, a second resist pattern 102b made of an unexposed portion of the resist film 102 and having a line width of 0.07 μm is formed in a good shape as shown in FIG. 9D.

In this manner, according to Embodiment 3, in the case where the first pattern exposure using the first mask and the second pattern exposure using the second mask having a smaller pattern size than the first mask are carried out, the first liquid 71E having a refractive index of 1.51 and the second liquid 71F having a refractive index of 1.58 are respectively used in the first pattern exposure and the second pattern exposure. Therefore, since the focal depth can be prevented from reducing in the first pattern exposure, the first resist pattern 102a with a large pattern size can be easily focused and can be formed in a good shape. In addition, since the second liquid 71F having a larger refractive index than the first liquid 71E is used in the second pattern exposure, the second resist pattern 102b can be formed also in a good shape. Accordingly, the resist patterns can be formed in a good shape regardless of their pattern sizes.

In each of Embodiments 1 through 3, water or water including an additive used as the immersion liquid may be replaced with perfluoropolyether or perfluoropolyether including an additive.

Moreover, although ArF excimer laser is used as the exposing light in each of Embodiments 1 through 3, KrF excimer laser, Xe₂ laser, F₂ laser, KrAr laser or Ar₂ laser may be used instead.

As described so far, in the exposure system, the exposure method and the method for fabricating a semiconductor device according to the invention, patterns can be formed in a good shape regardless of the degree of their pattern densities. Accordingly, the invention is useful for fabrication process or the like for semiconductor devices.

What is claimed is:

1. An exposure system comprising:
an exposure part for irradiating a resist film formed on a substrate with exposing light through a mask with a liquid provided on said resist film; and
a liquid supply part for supplying said liquid to said exposure part,
wherein said liquid supplying part includes a plurality of liquid units respectively containing a plurality of liquids having different refractive indexes, and a selection unit for selecting one liquid unit from said plurality of liquid units and supplying a liquid contained in said selected liquid unit to said exposure part.

2. An exposure method comprising the steps of:
exposing a first pattern onto a first resist film formed on a first substrate with a first liquid provided on said first resist film; and
exposing a second pattern having a different pattern size from said first pattern onto a second resist film formed on a second substrate with a second liquid having a different refractive index from said first liquid provided on said second resist film.

3. The exposure method of claim 2,
wherein said second pattern has a larger pattern size than said first pattern.

4. The exposure method of claim 2,
wherein said second liquid has a smaller refractive index than said first liquid.

5. A method for fabricating a semiconductor device comprising the steps of:
forming a first resist film on a first substrate;
performing first pattern exposure by irradiating said first resist film with exposing light through a first mask having a first pattern with a first liquid provided on said first resist film;
forming a first resist pattern by developing said first resist film after the first pattern exposure;
forming a second resist film on a second substrate;
performing second pattern exposure by irradiating said second resist film with said exposing light through a second mask having a second pattern with a second liquid having a different refractive index from said first liquid provided on said second resist film; and
forming a second resist pattern by developing said second resist film after the second pattern exposure.

6. The method for fabricating a semiconductor device of claim 5,
wherein said second pattern has a larger pattern size than said first pattern and said second liquid has a smaller refractive index than said first liquid.

7. The exposure method of claim 2,
said first substrate and said second substrate are one and the same substrate.

8. The method for fabricating a semiconductor device of claim 5,
said first substrate and said second substrate are one and the same substrate.

9. The exposure method of claim 2,
wherein said first pattern and said second pattern are different in pattern density.

10. The method for fabricating a semiconductor device of claim 5,
wherein said first pattern and said second pattern are different in pattern density.

11. The exposure system of claim 1,
wherein said liquid is water, water including an additive or perfluoropolyether.

12. The exposure system of claim 11,
wherein said additive is cesium sulfate or ethyl alcohol.

13. The exposure method of claim 2,
wherein each of said first liquid and said second liquid is water, water including an additive or perfluoropolyether.

14. The exposure method of claim 13,
wherein said additive is cesium sulfate or ethyl alcohol.

15. The method for fabricating a semiconductor device of claim 5,
wherein each of said first liquid and said second liquid is water, water including an additive or perfluoropolyether.

16. The method for fabricating a semiconductor device of claim 15,
wherein said additive is cesium sulfate or ethyl alcohol.

17. The exposure system of claim 1,
wherein said exposing light is KrF excimer laser, Xe₂ laser, ArF excimer laser, F₂ laser, KrAr laser or Ar₂ laser.

18. The exposure method of claim 2,
wherein a light source used for exposing is KrF excimer laser, Xe₂ laser, ArF excimer laser, F₂ laser, KrAr laser or Ar₂ laser.

19. The method for fabricating a semiconductor device of claim 5,
wherein said exposing light is KrF excimer laser, Xe₂ laser, ArF excimer laser, F₂ laser, KrAr laser or Ar₂ laser.
